(19) United States
(12) Patent Application Publication
(10) Pub. No.: US 2025/0071973 A1
(43) Pub. Date: Feb. 27, 2025

(54) SEMICONDUCTOR STRUCTURE, METHOD FOR MANUFACTURING SAME, AND MEMORY

(71) Applicant: CXMT CORPORATION, Hefei (CN)

(72) Inventor: Chao LIN, Hefei (CN)

(21) Appl. No.: 18/948,545

(22) Filed: Nov. 15, 2024

Related U.S. Application Data
(63) Continuation of application No. PCT/CN2023/089232, filed on Apr. 19, 2023.

(30) Foreign Application Priority Data
Nov. 7, 2022 (CN) 202211386456.7

(51) Int. Cl. H10B 12/00

(52) U.S. Cl. CPC H10B 12/315; H10B 12/05

(57) ABSTRACT

Provided are a semiconductor structure, a method for manufacturing same, and a memory. The semiconductor structure includes the following: a substrate; multiple transistor groups located on the substrate and arranged in an array, where each transistor group includes a first transistor and a second transistor; and the first transistor and the second transistor each include: a channel region; a source and a drain located at two opposite ends of the channel region; and a gate located on a side, in two opposite sides of the channel region, away from another transistor; and multiple connection structures located between a channel region of the first transistor and a channel region of the second transistor, where the channel region of the first transistor is connected to the channel region of the second transistor by the connection structure.

### CROSS-REFERENCE TO RELATED APPLICATIONS

This application is a continuation of PCT/CN2023/089232, filed on Apr. 19, 2023, which claims priority to Chinese Patent Application No. 202211386456.7, filed on Nov. 7, 2022, which are incorporated herein by reference in their entireties.

### TECHNICAL FIELD

Embodiments of the present disclosure relate to but are not limited to a semiconductor structure, a method for manufacturing same, and a memory.

### BACKGROUND

With the rapid increase in the penetration rate of electronic devices and the booming development of the electronic device market, there is a growing demand for electronic products with high performance, multi-functionality, high reliability, and convenience while evolving in the direction of miniaturization and thinning. Such a demand puts forward higher requirements on the structure and preparation technique of a memory.

### SUMMARY

According to one aspect, an embodiment of the present disclosure provides a semiconductor structure, including:
a substrate;
multiple transistor groups located on the substrate and arranged in an array in a first direction and a second direction intersecting with each other, where each of the transistor groups includes a first transistor and a second transistor arranged in parallel in the first direction; and the first transistor and the second transistor each include:
a channel region;
a source and a drain, located at two opposite ends of the channel region in a third direction, where the third direction is perpendicular to the surface of the substrate, and both the first direction and the second direction are perpendicular to the third direction; and
a gate, located on the side, in two opposite sides of the channel region in the first direction, away from another transistor; and
multiple connection structures, located between a channel region of the first transistor and a channel region of the second transistor, where the channel region of the first transistor is connected to the channel region of the second transistor by the connection structure.

According to one aspect, an embodiment of the present disclosure provides a memory, including the semiconductor structure described in the foregoing embodiment of the present disclosure.

According to one aspect, an embodiment of the present disclosure provides a method for manufacturing a semiconductor structure, including the following steps.

A base is provided.

Multiple transistor groups arranged in an array in a first direction and a second direction intersecting with each other are formed on the base; each of the transistor groups includes a first transistor and a second transistor arranged in parallel in the first direction; and the first transistor and the second transistor each include:
a channel region;
a source and a drain, located at two opposite ends of the channel region in a third direction, where the third direction is perpendicular to the surface of the base, and both the first direction and the second direction are perpendicular to the third direction; and
a gate, located on the side, in two opposite sides of the channel region in the first direction, away from another transistor.

Multiple connection structures are formed between a channel region of the first transistor and a channel region of the second transistor, and the channel region of the first transistor is connected to the channel region of the second transistor by the connection structure.

### BRIEF DESCRIPTION OF DRAWINGS

FIG. 1a is a schematic diagram of memory cell array arrangement of a 6F² architecture according to an embodiment of the present disclosure;

FIG. 1b is a schematic diagram of memory cell array arrangement of a 4F² architecture according to an embodiment of the present disclosure;

FIG. 2 is a schematic flowchart of a method for manufacturing a semiconductor structure according to an embodiment of the present disclosure; and

FIG. 3a to FIG. 3v are schematic flowcharts of manufacturing processes of a semiconductor structure according to embodiments of the present disclosure.

In the foregoing accompanying drawings (which are not necessarily drawn to scale), similar reference numerals may describe similar components in different views. Different examples of the similar components may be represented by similar reference numerals with different letter suffixes. Various embodiments discussed herein are generally illustrated by the accompanying drawings by way of example and not limitation.

### DESCRIPTION OF EMBODIMENTS

To make the technical solutions and advantages of the embodiments of the present disclosure clearer, the technical solutions of the present disclosure are further described below in detail with reference to the accompanying drawings and the embodiments. Although example implementation methods of the present disclosure are shown in the accompanying drawings, it should be understood that the present disclosure may be implemented in various forms without being limited by the implementations described herein. Instead, these implementations are provided to develop a more thorough understanding of the present disclosure and to fully convey the scope of the present disclosure to a person skilled in the art.

In the following paragraphs, the present disclosure is described more specifically by way of example with reference to the accompanying drawings. The advantages and features of the present disclosure will be clearer from the following description and claims. It should be noted that the accompanying drawings are presented in a highly simplified form and are not to exact scale, and are merely intended to conveniently and clearly assist in describing the embodiments of the present disclosure.

It may be understood that meanings of “on”, “over”, and “above” in the present disclosure should be understood in the widest way, so that “on” means that it is “on” something with no intermediate feature or layer (that is, directly on something), and further includes the meaning that it is “on” something with an intermediate feature or layer.

In addition, for ease of description, spatially relative terms such as “on”, “over”, “above”, “up”, and “upper” may be adopted herein to describe a relationship of one element or feature to another element or feature as shown in the figures. The spatially relative terms are intended to cover different orientations of the device in application or operation in addition to the orientation depicted in the accompanying drawings. The apparatus may be oriented in another manner (rotated by 90 degrees or in another orientation), and the spatially relative descriptors adopted herein can likewise be interpreted accordingly.

In the embodiments of the present disclosure, the term “substrate” refers to a material on which a subsequent material layer is added. The substrate itself may be patterned. A material added to the top of the substrate may be patterned or may remain unpatterned. In addition, multiple semiconductor materials may be included by the substrate, e.g., silicon, silicon germanium, germanium, gallium arsenide, and indium phosphide. Alternatively, the substrate may be made of a non-conductive material, e.g., glass, plastic, or a sapphire wafer.

In the embodiments of the present disclosure, the term “layer” refers to a material part including a region having a thickness. The layer may extend over the whole of a lower or upper structure, or may have a range smaller than the range of the lower or upper structure. In addition, the layer may be a region of a homogeneous or heterogeneous continuous structure whose thickness is thinner than the thickness of a continuous structure. For example, the layer may be located between the top surface and the bottom surface of the continuous structure, or the layer may be between any horizontal surface pair at the top surface and the bottom surface of the continuous structure. The layer may extend horizontally, vertically, and/or along an inclined surface. Multiple sublayers may be included in the layer. For example, one or more conductors and contact sublayers (in which interconnection lines and/or via-hole contacts are formed) and one or more dielectric sublayers may be included in an interconnection layer.

In the embodiments of the present disclosure, the terms “first”, “second”, and the like are intended to distinguish between similar objects but do not necessarily indicate a specific order or sequence. It should be noted that the technical solutions described in the embodiments of the present disclosure may be randomly combined when there is no conflict.

It should be noted that, for clear description of the present disclosure, in the following embodiments, a first direction intersects a second direction, that is, the included angle between the first direction and the second direction is any angle between 0 degrees to 90 degree. For ease of understanding, that the first direction is perpendicular to the second direction serves as an example for description. It may be understood that the locational relationship between multiple active pillars in array arrangement in the first direction and the second direction is established by the included angle between the first direction and the second direction. A third direction is perpendicular to both the first direction and the second direction. For example, the first direction is the X-axis direction shown in the accompanying drawings. The second direction is the Y-axis direction shown in the accompanying drawings. The third direction is the Z-axis direction shown in the accompanying drawings. However, it should be noted that the description of the direction in the following embodiments is merely adopted to describe the present disclosure, and is not intended to limit the scope of the present disclosure.

In addition, schematic diagrams of various structures according to the embodiments of the present disclosure are shown in the accompanying drawings. These figures are not drawn to scale. Some details are magnified for the sake of clarity and some details may be omitted. In the figures, shapes of various regions and layers, and relative sizes of and location relationships between the various regions and layers are merely examples, and may deviate in practice due to manufacturing tolerances or technical limitations. In addition, a person skilled in the art may additionally design regions/layers with different shapes, sizes, and relative locations according to actual requirements.

The memory included in the embodiments of the present disclosure includes but is not limited to a dynamic random access memory (DRAM). However, it should be noted that the description about the dynamic random access memory in the following embodiments is merely adopted to describe the present disclosure, and is not intended to limit the scope of the present disclosure.

It may be understood that a peripheral circuit and a memory cell array may be included in the dynamic random access memory. The peripheral circuit may include any suitable digital, analog, and/or mixed signal circuit configured to facilitate the memory to implement various operations such as a read operation, a write operation, and an erase operation. For example, control logic (e.g., a control circuit or a controller), a data buffer, a decoder (a decoder may also be referred to as a code translator), a driver, a read/write circuit, and the like may be included in the peripheral circuit. When a read/write operation command and address data are received by the control logic, under the action of the control logic, a corresponding voltage obtained from the driver may be applied by the decoder based on the decoded address to a corresponding bit line and word line, to implement data read/write, and exchange data with the outside through the data buffer.

Multiple memory cells may be included in the memory cell array. One transistor and one capacitor may be included in the structure of each memory cell, that is, the dynamic random access memory has an architecture of one transistor (T) and one capacitor (C) (1T1C). Alternatively, two transistors may be included, that is, the dynamic random access memory has an architecture of two transistors (T) and zero capacitors (C) (2T0C). However, it should be understood that, regardless of whether the dynamic random access memory has the 1T1C architecture or the 2T0C architecture, the main operating principle thereof is that whether one binary bit is 1 or 0 is represented by a quantity of charges stored in a storage node between the capacitor or the two transistors.

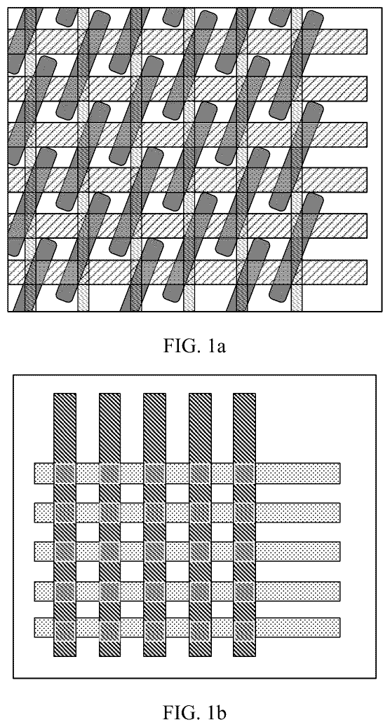

With development of a dynamic random access memory technology, the size of the memory cell array becomes increasingly smaller, and an array architecture thereof ranges from 8F² to 6F² (FIG. 1a), then to 4F² (FIG. 1b). In addition, based on a requirement for an ion and a leakage current in the dynamic random access memory, the architecture of the memory ranges from a planar array transistor to a recess gate array transistor, from the recess gate array transistor to a buried channel array transistor, and from the buried channel array transistor to a vertical channel array transistor. However, the size of both a planar transistor and a buried transistor gradually decreases. In this case, spacing between adjacent transistors gradually decreases, and cumulative holes generated due to a floating body effect (FBE) accumulate between channel regions of two adjacent transistors. Consequently, coupling capacitance is generated and gradually increases, affecting memory performance.

It should be noted that FIG. 1a is a schematic diagram of a 6F² memory cell array architecture, and FIG. 1b is a schematic diagram of a 4F² memory cell array architecture.

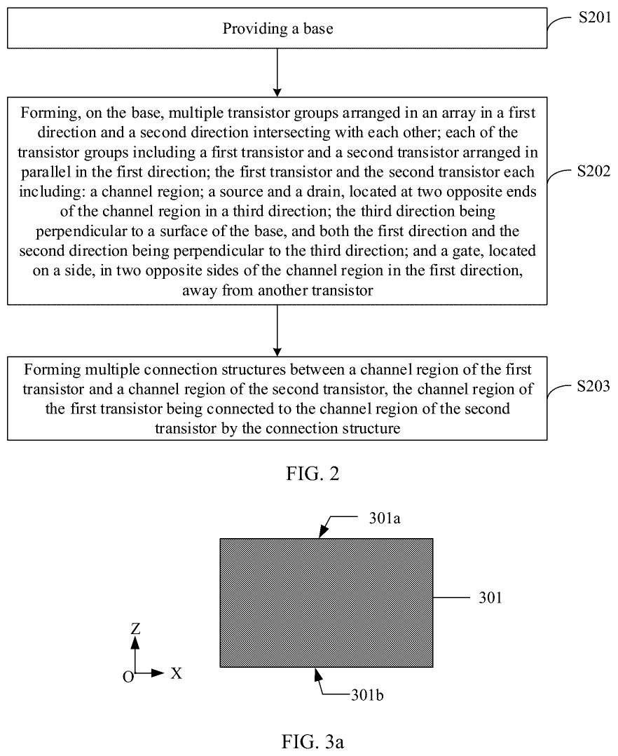

Based on this, to resolve one or more of the foregoing problems, embodiments of the present disclosure provide a semiconductor structure, a method for preparing same, and a memory, which can reduce technique difficulty, and reduce parasitic capacitance while increasing integration density, and improve performance of the memory. FIG. 2 is a schematic flowchart of an implementation of a method for manufacturing a semiconductor structure according to an embodiment of the present disclosure. As shown in FIG. 2, the method for manufacturing a semiconductor structure includes the following steps:

In the step of S201, a base is provided.

In the step of S202, multiple transistor groups arranged in an array in a first direction and a second direction intersecting with each other are formed on the base; each of the transistor groups includes a first transistor and a second transistor arranged in parallel in the first direction; and the first transistor and the second transistor each include:
a channel region;
a source and a drain, located at two opposite ends of the channel region in a third direction, where the third direction is perpendicular to the surface of the base, and both the first direction and the second direction are perpendicular to the third direction; and
a gate, located on the side, in two opposite sides of the channel region in the first direction, away from another transistor.

In the step of S203, multiple connection structures are formed between a channel region of the first transistor and a channel region of the second transistor, and the channel region of the first transistor is connected to the channel region of the second transistor by the connection structure.

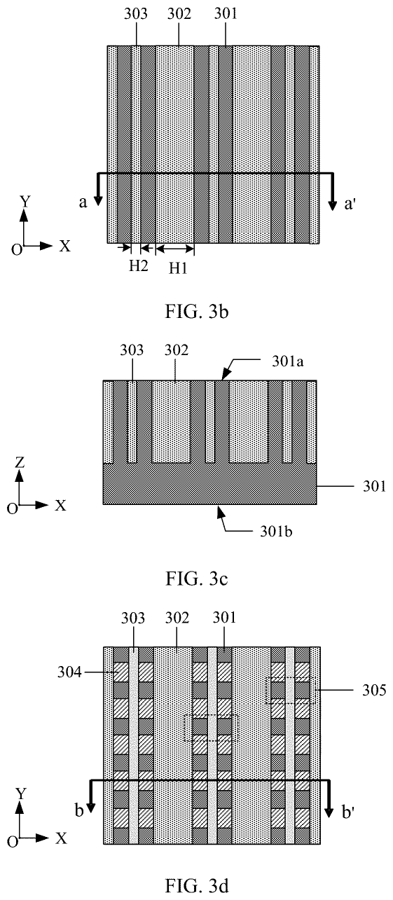

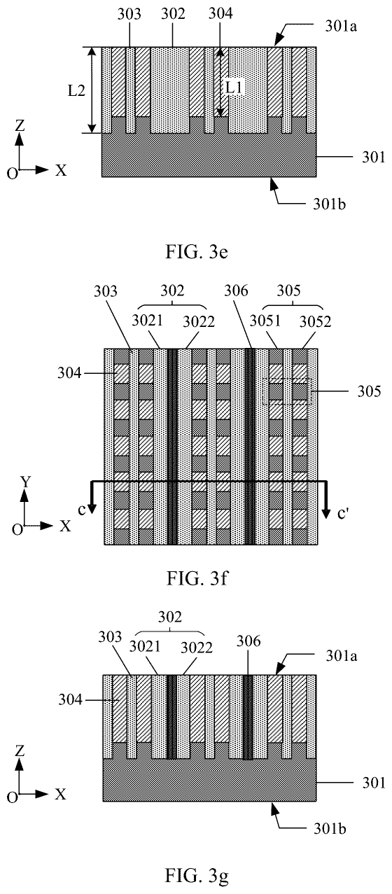

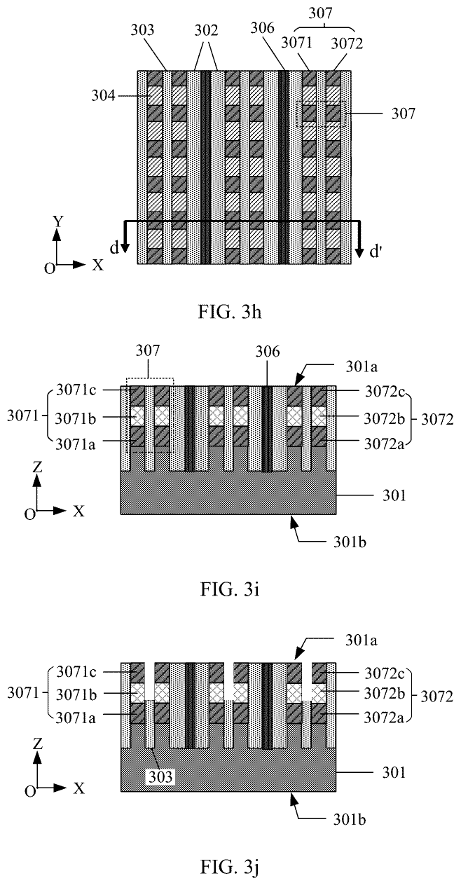

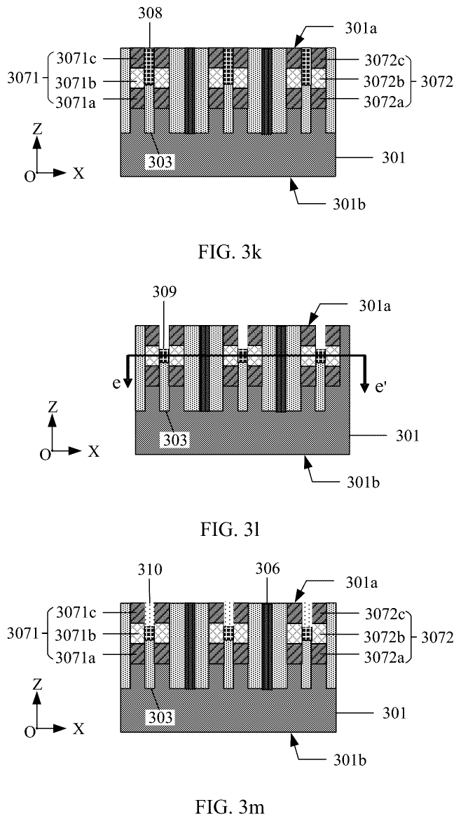

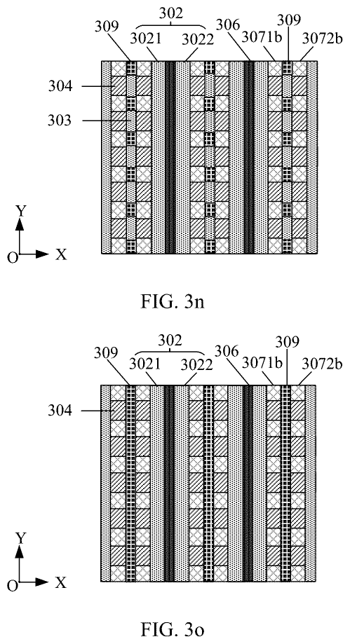

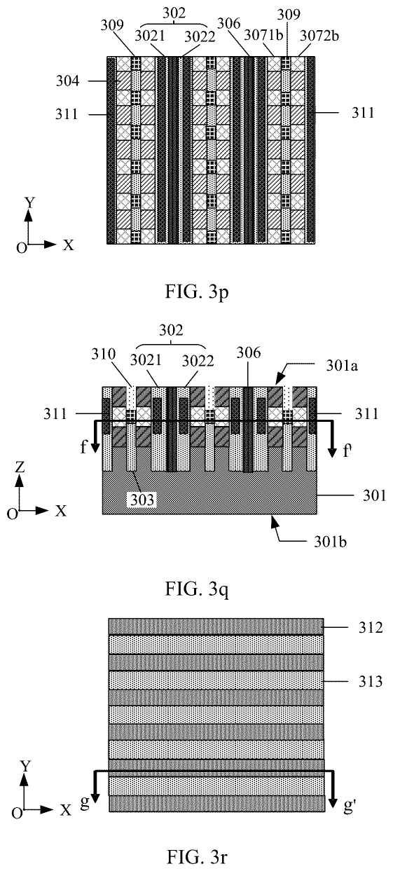

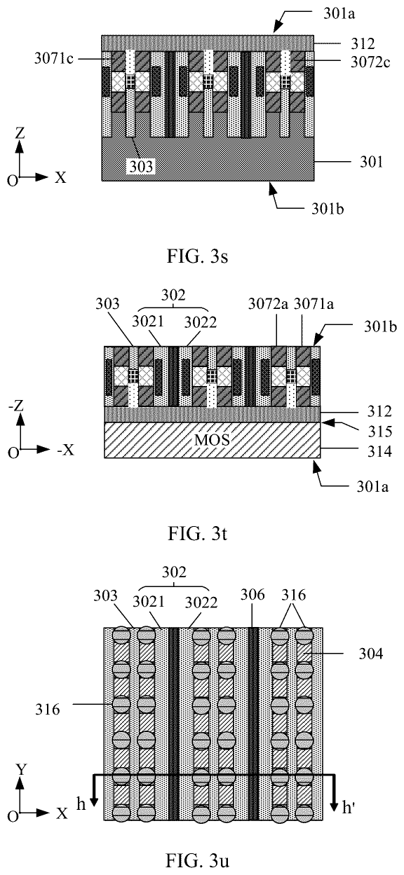

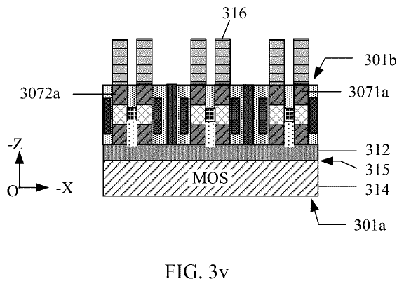

It should be understood that the steps shown in FIG. 2 are not exclusive, and another step may be performed before, after, or between any steps in the operations shown. The sequence of the steps shown in FIG. 2 may be adjusted according to an actual requirement. FIG. 3a to FIG. 3v are schematic cross-sectional diagrams of a manufacturing process of a semiconductor structure according to an embodiment of the present disclosure. With reference to FIG. 2 and FIG. 3a to FIG. 3v, the method for manufacturing a semiconductor structure provided in the embodiments of the present disclosure is described below in detail.

Step S201 is performed to provide a base.

Referring to FIG. 3a, a base 301 has a first surface 301a and a second surface 301b, and the first surface and the second surface are two surfaces of the base opposite to each other in a third direction. The third direction is the thickness direction of the base 301. For example, the third direction is the Z-axis direction. The material of the base 301 includes but is not limited to silicon (Si), germanium (Ge), silicon germanium (SiGe), and the like.

Step S202 is performed, to form, on the base, multiple transistor groups arranged in an array in a first direction and a second direction intersecting with each other.

In some embodiments, the forming, on the base, multiple transistor groups arranged in an array in a first direction and a second direction intersecting with each other includes the following steps.

Multiple first trenches and multiple second trenches arranged at intervals in the first direction are formed on a first surface of the base, and multiple third trenches arranged in an array in the first direction and the second direction are formed on the remaining part of the base; the base is divided by the first trench, the second trench, and the third trench into multiple active pillar groups; and the active pillar groups is divided by the second trench into a first active pillar and a second active pillar.

Doping processing is separately performed on a first end and a second end, opposite to each other in the third direction, of each of the first active pillar and the second active pillar, and the middle part between the two ends, to form a source, a drain, and a channel region; the doped first active pillar is configured to form the first transistor, and the doped second active pillar is configured to form the second transistor; the first end is the end close to a second surface of the base; and the first surface and the second surface are two surfaces of the base opposite to each other in the third direction.

For example, a mask layer is deposited on the first surface 301a of the base, a photoresist is coated on the mask layer, exposure and development are performed on the photoresist, and the photoresist is removed through dissolution or ashing, to finally form a first mask layer with a preset pattern. The preset pattern may be understood as patterns of multiple first trenches and multiple second trenches spaced from each other in the X-axis direction. The material of the first mask layer may be, e.g., silicon nitride.

Next, the base 301 is etched by adopting the first mask layer, and a part of the base 301 is removed to form the multiple first trenches and the multiple second trenches arranged at intervals in the X-axis direction. Each first trench and each second trench extend in the Y-axis direction. Herein, the width of the first trench in the X-axis direction is H1, and the width of the second trench in the X-axis direction is H2. The width H1 of the first trench in the X-axis direction is greater than the width H2 of the second trench in the X-axis direction, that is, H1>H2.

It should be noted that FIG. 3b is a top view of an XOY plane (which may also be understood as the first surface of the base), FIG. 3c is a sectional view of an XOZ plane view, and FIG. 3c is a sectional view of FIG. 3b along a section a-a′.

Next, referring to FIG. 3b and FIG. 3c, before the third trench is formed, a first insulating layer 302 is formed in the first trench, and a second insulating layer 303 is formed in the second trench. The material of the first insulating layer 302 may be the same as or different from the material of the second insulating layer 303. Preferably, the material of the first insulating layer 302 is the same as the material of the second insulating layer 303. For example, the materials of the first insulating layer 302 and the second insulating layer 303 both include silicon oxide (SiO2). A method for forming the first insulating layer 302 and the second insulating layer 303 includes but is not limited to techniques such as physical vapor deposition (PVD), chemical vapor deposition (CVD), and atomic layer deposition (ALD).

Next, referring to FIG. 3c, chemical mechanical polishing (CMP) is performed on the first insulating layer 302 and the second insulating layer 303, so that surfaces of the first insulating layer 302 and the second insulating layer 303 close to the first surface are basically flush with the first surface of the base 301.

It should be understood that “basically flush” mentioned herein and below may be understood as being flush or approximately flush. A non-flush case caused by an error in an actual technique preparation is within the range of being basically flush or approximately flush.

Next, a second mask layer with a preset pattern of the third trench is formed on the first surface of the base 301. The second mask layer and the first mask layer are the same in terms of the forming method and the material, which have been described above. Details are not described herein again.

Next, the remaining part of the base 301 is etched by adopting the second mask layer. After a part of the base 301 is removed, the multiple third trenches arranged in an array in the X-axis direction and the Y-axis direction are formed. The depth of the third trench in the third direction is less than the depth of the first trench and the second trench in the third direction. For example, the depth of the third trench in the Z-axis direction is a first distance L1, and the depth of the first trench and the second trench in the Z-axis direction is a second distance L2. Herein, the first distance is less than the second distance, that is, L1<L2.

It should be noted that FIG. 3d is a top view of an XOY plane, FIG. 3e is a top view of an XOZ plane, and FIG. 3e is a sectional view of FIG. 3d along a section b-b′.

Next, referring to FIG. 3d and FIG. 3e, a third insulating layer 304 is formed in the third trench. The material of the third insulating layer 304 is different from the materials of the first insulating layer and the second insulating layer. For example, the material of the third insulating layer 304 includes but is not limited to silicon nitride (SiN). A method for forming the third insulating layer includes but is not limited to techniques such as PVD and CVD. In some specific embodiments, the first insulating layer and the second insulating layer may be further understood as first shallow trench isolation (STI) and second shallow trench isolation.

It should be noted that, because the depth of the third trench in the Z-axis direction is less than the depth of the first trench and the second trench in the Z-axis direction, the depth of the third insulating layer 304 in the Z-axis direction is less than the depth of the first insulating layer and the second insulating layer in the Z-axis direction. For example, referring to FIG. 3e, the depth of the third insulating layer in the Z-axis direction is a first distance L1, and the depth of the first insulating layer and the second insulating layer in the Z-axis direction is a second distance L2. Herein, the first distance is less than the second distance, that is, L1<L2.

Next, referring to FIG. 3e, chemical mechanical polishing is performed on the third insulating layer 304, so that the top surface of the third insulating layer 304 is basically flush with the first surface 301a of the base 301. In other words, after chemical mechanical polishing is performed, the surfaces of the first insulating layer, the second insulating layer, and the third insulating layer close to the first surface 301a each are exposed, and are basically flush with the first surface.

It should be noted that the first insulating layer 302 is filled in the first trench, and in this case, the width of the first insulating layer 302 in the X-axis direction is H1. The second insulating layer 303 is filled in the second trench, and in this case, the width of the second insulating layer 303 in the X-axis direction is H2. Herein, the width H1 of the first insulating layer 302 in the X-axis direction is greater than the width H2 of the second insulating layer 303 in the X-axis direction, that is, H1>H2. Therefore, the distance between transistors formed on two sides of the second insulating layer can be reduced, thereby reducing the size of the semiconductor structure and increasing integration density of the memory.

It should be understood that, referring to FIG. 3d, the base 301 is divided by the first trench, the second trench, and the third trench into multiple active pillar groups 305 (shown in a dashed-line box in FIG. 3d) arranged in an array in the X-axis direction and the Y-axis direction. Each of the active pillar groups 305 includes a first active pillar 3051 and a second active pillar 3052, and the first active pillar 3051 and the second active pillar 3052 are separated by the second trench.

It should be noted that FIG. 3f is a top view of an XOY plane, FIG. 3g is a top view of an XOZ plane, and FIG. 3g is a sectional view of FIG. 3f along a section c-c′.

In some embodiments, referring to FIG. 3f and FIG. 3g, the first insulating layer is etched to form a gap extending in the second direction and penetrating the second insulating layer. The second insulating layer is divided by the gap into two sub-insulating layers (3021 and 3022 shown in FIG. 3f, FIG. 3g, FIG. 3n, FIG. 30, FIG. 3p, FIG. 3q, and the like) arranged in parallel in the first direction. Then, a gap material layer is deposited in the gap to form an isolation structure 306. The material of the isolation structure 306 includes but is not limited to silicon nitride, silicon oxide, or another low dielectric material (with a low k). Adopting the isolation structure can reduce coupling capacitance between two adjacent transistor groups.

It should be noted that FIG. 3h is a top view of an XOY plane, FIG. 3i is a top view of an XOZ plane, and FIG. 3i is a sectional view of FIG. 3h along a section d-d′.

Next, referring to FIG. 3h and FIG. 3i, doping processing is separately performed on a first end and a second end, opposite to each other in the third direction, of each of the first active pillar 3051 and the second active pillar 3052, and the middle part between the two ends, to form a source, a drain, and a channel region.

For example, ion doping is performed on both the first end of the first active pillar 3051 and the first end of the second active pillar 3052 to respectively form one of the source and the drain. Herein, doping types of the first end of the first active pillar and the first end of the second active pillar are the same. Ion doping is performed on the second end of the first active pillar 3051 and the second end of the second active pillar 3052 to form the remaining one of the source and the drain. Herein, doping types of the second end of the first active pillar 3051 and the second end of the second active pillar 3052 are the same. Ion doping is performed on both the middle part between the first end and the second end of the first active pillar 3051 and the middle part between the first end and the second end of the second active pillar 3052, to form the channel region. Herein, doping types of the middle part of the first active pillar 3051 and the middle part of the second active pillar 3052 are the same. It should be noted that, in some other embodiments, before the active pillar group is formed, doping processing is performed on the base. In this case, doping is no longer performed on the middle part between the first end and the second end of the active pillar. In other words, after doping is performed on the first end and the second end of the active pillar, the channel region is formed between the first end and the second end.

Herein, the first end and the second end are respectively two opposite ends of the first active pillar 3051 and the second active pillar 3052 in the Z-axis direction. In addition, the first end is the end close to the second surface 301b of the base, and the second end is the end close to the first surface 301a of the base. Herein, the doping types of the first end and the second end are the same, and the doping types of the first end and the second end are different from the doping types of the middle parts.

For ease of understanding, for example, a first source 3071a is formed at the first end of the first active pillar, a second source 3072a is formed at the first end of the second active pillar, a first drain 3071c is formed at the second end of the first active pillar, a second drain 3072c is formed at the second end of the second active pillar, a first channel region 3071b is formed in the middle part of the first active pillar, and a second channel region 3072b is formed in the middle part of the second active pillar. It should be understood that locations of the source and the drain formed in the active pillar may be interchanged. Descriptions of the locations of the source and the drain in the following embodiments are merely adopted to describe the present disclosure, and are not intended to limit the scope of the present disclosure.

Doping types of the first source 3071a, the second source 3072a, the first drain 3071c, and the second drain 3072c are the same, and are different from doping types of the first channel region 3071b and the second channel region 3072b. For example, the doping types of the first source 3071a, the second source 3072a, the first drain 3071c, and the second drain 3072c are an N-type, and the doping types of the first channel region 3071b and the second channel region 3072b are a P-type. Alternatively, the doping types of the first source 3071a, the second source 3072a, the first drain 3071c, and the second drain 3072c are a P-type, and the doping types of the first channel region 3071b and the second channel region 3072b are an N-type. It should be understood that types of transistors vary with types of doped ions.

An ion implantation technique, a diffusion technique, and the like are included in the doping processing technique. In an actual operation, generally, after an ion implantation technique operation or a diffusion technique operation is performed, it is necessary to perform annealing processing on the formed source, drain, channel region, and the like. In actual application, an annealing technique is relatively mature. Details are not described herein again.

It should be noted that, to describe and understand the structure of the transistor group more clearly, a word line and a gate in the transistor group are separately described in this embodiment of the present disclosure. However, in actual application, the gate and the word line may be formed separately or together. In some other embodiments, the gate is combined into the word line. In this embodiment of the present disclosure, the gate and the word line are formed together. Based on this, a process of forming the word line is described in detail in the following. Details are not described herein again.

Herein, the doped first active pillar 3051 is configured to form a first transistor 3071, the doped second active pillar 3052 is configured to form a second transistor 3072, and the first transistor 3071 and the second transistor 3072 form a transistor group 307.

Step S203 is performed, to form multiple connection structures between a channel region of the first transistor and a channel region of the second transistor.

In some embodiments, the forming multiple connection structures includes the following steps.

A part of the second insulating layer is removed, where the surface of the remaining part of the second insulating layer away from the second surface is higher than the surface of the first end of each of the first active pillar and the second active pillar away from the second surface.

A connection structure material layer is filled at the location at which the second insulating layer is removed.

A part of the connection structure material layer is removed, where the surface of the remaining part of the connection structure material layer away from the second surface is lower than the surface of the second end of each of the first transistor and the second transistor away from the first surface; and the remaining part of the connection structure material layer is configured to form the connection structure.

Referring to FIG. 3j, the part of the second insulating layer 303 located in the second trench is removed along the first surface 301a of the base 301. The surface of the remaining part of the second insulating layer 303 away from the second surface 301b of the base is higher than the surfaces of the first source 3071a and the second source 3072a away from the second surface 301b of the base. The removal technique includes but is not limited to etching, e.g., dry etching and wet etching.

Referring to FIG. 3k, a connection structure material layer 308 is filled at the location at which the second insulating layer 303 is removed. The material of the connection structure material layer 308 includes but is not limited to polysilicon, silicon, germanium, and the like. A method for forming the connection structure material layer includes but is not limited to techniques such as PVD, CVD, and ALD. It should be noted that the materials of the connection structure and the channel region may be the same or different.

Referring to FIG. 3l, a part of the connection structure material layer 308 is removed along the first surface 301a of the base 301, and a connection structure 309 is formed by the remaining part of the connection structure material layer 308. The surface of the connection structure 309 away from the second surface 301b of the base is lower than the surfaces of the first drain 3071c and the second drain 3072c away from the first surface 301a of the base. Herein, the connection structure 309 is not in contact with all the first source 3071a, the second source 3072a, the first drain 3071c, and the second drain 3072c, and is only configured to electrically connect the channel region of the first transistor (namely, the first channel region 3071b) to the channel region of the second transistor. In this way, during application of the transistor group, cumulative holes generated between the first channel region and the second channel region due to a floating body effect can be conducted, split, or removed, thereby reducing generation of parasitic capacitance and improving performance of a transistor. The removal technique includes but is not limited to etching, e.g., dry etching.

In some specific embodiments, the connection structure 309 is a doping structure, and the doping type of the connection structure 309 is the same as the doping types of the first channel region and the second channel region. For example, the doping types of the connection structure, the first channel region, and the second channel region all are P-type doping. Alternatively, the doping types of the connection structure, the first channel region, and the second channel region all are N-type doping. In addition, the doping concentration of the connection structure is greater than the doping concentration of the first channel region or the second channel region. In this way, by increasing the doping concentration of the connection structure, conduction, splitting, or removal of the cumulative hole can be accelerated.

Referring to FIG. 3m, a fourth insulating layer 310 is formed at the location at which the connection structure material layer 308 is removed, and the surface of the fourth insulating layer 310 away from the second surface 301b of the base is basically flush with the first surface 301a of the base. The material of the fourth insulating layer 310 may be the same as or different from the material of the second insulating layer. Herein, the material of the fourth insulating layer 310 includes but is not limited to silicon oxide. A method for forming the fourth insulating layer 310 includes but is not limited to techniques such as PVD, CVD, and ALD.

It should be noted that, in some embodiments, the method further includes the following steps.

The connection structure is directly formed by the remaining part of the connection structure material layer.

Alternatively,
the part of the second insulating layer between the third insulating layers adjacent to each other in the first direction that is corresponding to the remaining part of the connection structure material layer is removed, to form the connection structure.

It should be noted that both FIG. 3n and FIG. 30 are sectional views of FIG. 3l along a section e-e′.

Herein, referring to FIG. 3n, the remaining part of the connection structure material layer is directly formed into the connection structure 309. An orthographic projection of the connection structure 309 in the X-axis direction is located in orthographic projections of the first channel region and the second channel region in the X-axis direction. In other words, each connection structure 309 is configured to connect only channel regions on two sides of the connection structure 309 in the X-axis direction, that is, each connection structure 309 is located between a corresponding first channel region 3071b and a corresponding second channel region 3072b. In this way, one connection structure 309 is corresponding to one transistor group, thereby increasing a response speed and flexibility of each transistor group. In some other embodiments, referring to FIG. 30, the part of the second insulating layer that is between third insulating layers adjacent in the X-axis direction and that is corresponding to the remaining part of the connection structure material layer may be further removed, to form a connection structure extending in the Y-axis direction. Herein, each of the connection structures is connected to all first channel regions 3071b and all second channel regions 3072b in the multiple transistor groups arranged in parallel in the Y-axis direction. In this way, all the channel regions disposed in the Y-axis direction can be connected by the connection structures 309, helping improve the capability of conducting, splitting, or removal of the cumulative holes.

In some embodiments, the method further includes the following step.

A part of the first insulating layer is removed to form a word line material layer; the surface of the word line material layer close to the first surface is lower than the first surface; and the word line material layer is divided by the isolation structure into two word lines.

FIG. 3p is a top view of an XOY plane, FIG. 3q is a top view of an XOZ plane, and FIG. 3p is a sectional view of FIG. 3q along a section f-f.

Referring to FIG. 3p and FIG. 3q, a part of the first insulating layer 302 is removed by an etching technique, to form a word line material layer on the side, in two opposite sides of the gate in the X-axis direction, away from a channel region. For example, a word line material layer is formed on a side, in two opposite sides of a first gate in the X-axis direction, away from the first channel region, and a word line material layer is formed on a side, in two opposite sides of a second gate in the X-axis direction, away from the second channel region. Herein, each word line material layer is divided by the isolation structure 306 into two word lines 311. Multiple word lines are arranged at intervals in the X-axis direction, and each word line extends in the Y-axis direction. Herein, the surface of the word line 311 close to the first surface 301a of the base is lower than the first surface 301a of the base.

It should be noted that, in some embodiments, the isolation structure may be first formed, and then the word line is formed, or the word line may be first formed, and then the isolation structure is formed. An actual operation sequence may be selected and set according to an actual requirement. Herein, the material of the word line includes but is not limited to a metal (e.g., tungsten) or polysilicon. A method for forming the word line includes but is not limited to techniques such as PVD, CVD, and ALD.

In some embodiments, before the multiple word lines are formed, a gate oxide layer (not shown in FIG. 3i) is formed. The gate oxide layer is located between the gate and the channel region, and is configured to electrically isolate the channel region and the gate, to reduce a hot carrier effect. The material of the gate oxide layer includes but is not limited to silicon oxide. A method for forming the gate oxide layer includes but is not limited to techniques such as PVD, CVD, and ALD.

In some embodiments, the method further includes the following step.

Multiple bit lines are formed on the multiple first surfaces, the multiple bit lines are arranged in parallel in the second direction, and each of the bit lines is connected to a second end of each transistor in a row of transistor groups disposed in the first direction.

It should be noted that FIG. 3r is a top view of an XOY plane, FIG. 3s is a top view of an XOZ plane, and FIG. 3s is a sectional view of FIG. 3r along a section g-g′.

For example, referring to FIG. 3r and FIG. 3s, multiple of bit lines 312 are arranged in parallel in the Y-axis direction, and each of the bit lines 312 extends in the X-axis direction. In addition, each of the bit lines 312 is connected to a first drain 3071c and a second drain 3072c in a row of transistor groups disposed in the X-axis direction. The material of the bit line includes but is not limited to a metal (e.g., tungsten) or polysilicon. A method for forming the bit line includes but is not limited to techniques such as PVD, CVD, and ALD. In some embodiments, the method further includes the following step. A fifth insulating layer 313 is formed between adjacent bit lines, and may be configured to reduce parasitic capacitance formed between bit lines 312 on two sides of the fifth insulating layer 313, improving performance of the semiconductor structure. The material of the fifth insulating layer includes but is not limited to silicon oxide, silicon nitride, or another low dielectric material. A method for forming the fifth insulating layer 313 includes but is not limited to techniques such as PVD, CVD, and ALD.

In some embodiments, the method further includes the following steps.

A substrate is provided, to form a peripheral circuit in the substrate.

The base is bonded to the substrate, to form a bonding layer between the substrate and the bit line.

Thinning processing is performed on the second surface of the base after the bonding operation is performed, to expose a first end of each transistor in the transistor group.

For example, referring to FIG. 3t, a substrate 314 is provided, the substrate has a third surface and a fourth surface, the third surface and the fourth surface are two surfaces of the substrate opposite to each other in the thickness direction, and the thickness direction of the substrate is parallel to the Z-axis direction. The material of the substrate 314 may be the same as or different from the material of the base. Preferably, the material of the substrate 314 includes silicon, germanium, silicon germanium, and the like.

A peripheral circuit is formed in the substrate 314. Herein, the peripheral circuit may include any suitable digital, analog and/or mixed signal circuit that facilitates a memory to implement various operations such as a read operation, a write operation, and an erase operation. In this case, a voltage signal and/or a current signal may be applied to a corresponding semiconductor structure by adopting a corresponding bit line, a word line, and the like. A voltage signal and/or a current signal is sensed from each corresponding semiconductor structure to facilitate the corresponding semiconductor structure to perform an operation.

In some specific embodiments, various types of peripheral circuits formed by adopting a metal-oxide-semiconductor (MOS) technology may be further included by the peripheral circuit, e.g., a page buffer/sense amplifier, a column decoder/bit line driver, a row decoder/word line driver, a voltage generator, control logic, a register, an interface, and a data bus.

Next, the first surface 301a of the base is bonded to the third surface or the fourth surface of the substrate 314, to form a bonding layer 315 between the third surface or the fourth surface of the substrate 314 and the first surface 301a of the base. The bonding layer 315 electrically connects the bit line 312 located on the first surface 301a of the base to the peripheral circuit of the substrate 314.

In some embodiments, that the base is bonded to the substrate includes the following step.

The base is bonded to the substrate in a hybrid bonding manner.

Herein, the hybrid bonding is to separately combine metal films and dielectric films together without intermediate films. It may be understood that in a process of bonding the base to the substrate, a metal in the base and a metal in the substrate are combined together, and a dielectric film and another dielectric film are combined together without a need for any other material assistance in the middle. In some other embodiments, the base may be bonded to the substrate in another manner, e.g., a technique of hybrid bonding or melt bonding.

Next, referring to FIG. 3t, the bonded substrate and base are inverted, so that the second surface 301b of the base is exposed and becomes a top surface. It should be noted that, if the second surface 301b of the base already becomes the top surface after the substrate is bonded to the base, it is unnecessary to invert the substrate and the base. Then, thinning processing is performed on the second surface 301b of the base, to expose the third insulating layer (not shown in FIG. 3t) and the first source 3071a and the second source 3072a in each transistor group. Herein, the third insulating layer may serve as an etching stop layer for the thinning processing. A technique of the thinning processing includes but is not limited to chemical mechanical polishing. In some embodiments, the method further includes the following step.

Multiple storage structures are formed on the exposed first end of each transistor in the transistor group; each of the storage structures is connected to one of a source and a drain of a corresponding first transistor or one of a source and a drain of a corresponding second transistor.

It should be noted that FIG. 3u is a top view of an XOY plane, FIG. 3v is a top view of an XOZ (namely, (—X)O(—Z)) plane, and FIG. 3v is a sectional view of FIG. 3u along a cross-section h-h′.

For example, referring to FIG. 3u and FIG. 3v, multiple storage structures 316 are formed on an exposed first source 3071a of the first transistor and an exposed second source 3072a of the second transistor in each transistor group. Each of the storage structures 316 is correspondingly connected to the source of one transistor. In this way, the storage structure 316 can be self-aligned with the first source or the second source, increasing a technique window, and reducing technique difficulty. The shape of the storage structure 316 may be cylindrical, square, or any other suitable shape. The storage structure is configured to store data. In some specific embodiments, a capacitor, a transistor including a storage node, a magnetic tunnel junction, an adjustable resistor, or the like may be included by the storage structure.

Based on this, in the embodiments of the present disclosure, the multiple transistor groups arranged in an array are formed on the base. The first transistor and the second transistor disposed in parallel in the first direction are included by each transistor group. The first transistor and the second transistor each include the following: the channel region, the source and the drain respectively located at the two opposite ends of the channel region in the third direction, and the gate located on the side, in the two opposite sides of the channel region in the first direction, away from the another transistor. In addition, the connection structure is formed between the channel region of the first transistor and the channel region of the second transistor, and the channel region of the first transistor and the channel region of the second transistor are electrically connected by the connection structure. In this way, during application of the transistor group, the cumulative holes generated between the channel region of the first transistor and the channel region of the second transistor by the floating body effect can be conducted, split, or removed, thereby reducing generation of parasitic capacitance and improving performance of the transistor.

It should be noted that, in terms of material selection of the foregoing structures, any material that can implement a basic function of each layer may be adopted by each layer. However, to further improve electrical performance and an application effect of the memory, each layer has a preferred material.

Based on the foregoing method for forming the semiconductor structure, an embodiment of the present disclosure further provides a semiconductor structure, including:
a substrate;
multiple transistor groups located on the substrate and arranged in an array in a first direction and a second direction intersecting with each other, where each of the transistor groups includes a first transistor and a second transistor arranged in parallel in the first direction; and the first transistor and the second transistor each include:
a channel region;
a source and a drain, located at two opposite ends of the channel region in a third direction, where the third direction is perpendicular to the surface of the substrate, and both the first direction and the second direction are perpendicular to the third direction; and
a gate, located on the side, in two opposite sides of the channel region in the first direction, away from another transistor; and
multiple connection structures, located between a channel region of the first transistor and a channel region of the second transistor, where the channel region of the first transistor is connected to the channel region of the second transistor by the connection structure.

In some embodiments, an orthographic projection of the connection structure in the first direction is located in orthographic projections of the channel region of the first transistor and the channel region of the second transistor in the first direction.

In some embodiments, each of the connection structures is connected to the channel region of the first transistor and the channel region of the second transistor in one transistor group;
or
each of the connection structures is connected to channel regions of all the first transistors and channel regions of all the second transistors in the multiple transistor groups arranged in parallel in the second direction.

In some embodiments, materials of the connection structure and the channel region are the same or different.

In some embodiments, doping types of the source and the drain are the same; and doping types of the connection structure and the channel region are the same.

In some embodiments, the doping types of both the source and the drain are N-type doping; and the doping types of the connection structure and the channel region are P-type doping.

In some embodiments, a doping concentration of the connection structure is greater than a doping concentration of the channel region.

In some embodiments, the semiconductor structure further includes:
multiple storage structures, located on surfaces of the multiple transistor groups away from the substrate, where each of the storage structures is connected to one of the source and the drain of each transistor in the transistor group; and
multiple bit lines, located between the multiple transistor groups and the substrate and extending in the first direction, where each of the bit lines is connected to the remaining one of the source and the drain of each transistor in a row of transistor groups disposed in the first direction.

In some embodiments, the semiconductor structure further includes multiple isolation structures, and each of the isolation structures is located between two of the transistor groups adjacently disposed in the first direction.

In some embodiments, the semiconductor structure further includes:
multiple word lines, extending in the second direction, where each of the word lines is connected to the gate of each transistor in a row of transistor groups disposed in the second direction; and two word lines between the two of the transistor groups adjacently disposed in the first direction are separated by the isolation structure.

In some embodiments, a peripheral circuit is formed in the substrate.

In some embodiments, the semiconductor structure further includes a bonding layer, located between the substrate and the bit line, and both the word line and the bit line are connected to the peripheral circuit through the bonding layer.

An embodiment of the present disclosure further provides a memory, including the semiconductor structure described in the foregoing embodiments of the present disclosure.

In several embodiments provided in the present disclosure, it should be understood that the disclosed devices and methods may be implemented in a non-target manner. The device embodiments described above are merely examples. For example, the unit division is merely logical function division, and there may be another division manner in actual implementation. For example, multiple units or components may be combined or integrated into another system, or some features may be ignored or not performed. In addition, the displayed or discussed components are coupled to or directly coupled to each other.

The units described as separate parts may or may not be physically separate, and parts displayed as units may or may not be physical units, may be located in one position, or may be distributed on multiple network units. Some or all of the units may be selected according to an actual requirement to achieve the objectives of the solutions of the embodiments.

The features disclosed in the several method or device embodiments provided in the present disclosure may be randomly combined when there is no conflict, to obtain new method embodiments or new device embodiments.

The foregoing descriptions are merely specific implementations of the present disclosure, but are not intended to limit the protection scope of the present disclosure. Any variation or replacement readily figured out by a person skilled in the art within the technical scope disclosed in the present disclosure shall fall within the protection scope of the present disclosure. Therefore, the protection scope of the present disclosure shall be subject to the protection scope of the claims.

### INDUSTRIAL APPLICABILITY

In the embodiments of the present disclosure, the multiple transistor groups arranged in an array are formed on the base. The first transistor and the second transistor disposed in parallel in the first direction are included by each transistor group. The first transistor and the second transistor each include the following: the channel region, the source and the drain respectively located at the two opposite ends of the channel region in the third direction, and the gate located on the side, in the two opposite sides of the channel region in the first direction, away from the another transistor. In addition, the connection structure is formed between the channel region of the first transistor and the channel region of the second transistor, and the channel region of the first transistor and the channel region of the second transistor are electrically connected by the connection structure. In this way, during application of the transistor group, the cumulative holes generated between the channel region of the first transistor and the channel region of the second transistor due to the floating body effect can be conducted, split, or removed, thereby reducing generation of parasitic capacitance and improving performance of the transistor.

What is claimed is:

1. A semiconductor structure, comprising:
a substrate;
a plurality of transistor groups arranged in an array in a first direction and a second direction intersecting with each other, located on the substrate; each of the transistor groups comprising a first transistor and a second transistor arranged in parallel in the first direction; and, wherein the first transistor and the second transistor each comprises:
a channel region;
a source and a drain, located at two opposite ends of the channel region in a third direction;
the third direction being perpendicular to a surface of the substrate, and both the first direction and the second direction being perpendicular to the third direction;
a gate, located on a side, in two opposite sides of the channel region in the first direction, away from another transistor; and
a plurality of connection structures, located between a channel region of the first transistor and a channel region of the second transistor, the channel region of the first transistor being connected to the channel region of the second transistor by the connection structure.

2. The semiconductor structure according to claim 1, wherein an orthographic projection of the connection structure in the first direction is located in orthographic projections of the channel region of the first transistor and the channel region of the second transistor in the first direction.

3. The semiconductor structure according to claim 1, wherein each of the connection structures is connected to the channel region of the first transistor and the channel region of the second transistor in one transistor group.

4. The semiconductor structure according to claim 1, wherein each of the connection structures is connected to channel regions of all the first transistors and channel regions of all the second transistors in the plurality of transistor groups arranged in parallel in the second direction.

5. The semiconductor structure according to claim 1, further comprising:
a plurality of storage structures, located on surfaces of the plurality of transistor groups away from the substrate, each of the storage structures being connected to one of a source and a drain of each transistor in the transistor group; and
a plurality of bit lines, located on surfaces of the plurality of transistor groups close to the substrate, each of the bit lines extending in the first direction and being connected to a remaining one of a source and a drain of each transistor in a row of transistor groups disposed in the first direction.

6. The semiconductor structure according to claim 5, further comprising a plurality of isolation structures, each of the isolation structures being located between two of the transistor groups adjacently disposed in the first direction.

7. The semiconductor structure according to claim 6, further comprising:
a plurality of word lines, extending in the second direction; each of the word lines being connected to a gate of each transistor in a row of transistor groups disposed in the second direction;
and two word lines between the two of the transistor groups adjacently disposed in the first direction being separated by the isolation structure.

8. The semiconductor structure according to claim 7, wherein a peripheral circuit is formed in the substrate.

9. The semiconductor structure according to claim 8, further comprising a bonding layer, located between the substrate and the bit line wherein both the word line and the bit line are connected to the peripheral circuit through the bonding layer.

10. A memory, comprising the semiconductor structure according to claim 1.

11. A method for manufacturing a semiconductor structure, comprising:
providing a base;
forming, on the base, a plurality of transistor groups arranged in an array in a first direction and a second direction intersecting with each other; each of the transistor groups comprising a first transistor and a second transistor arranged in parallel in the first direction; the first transistor and the second transistor each comprising:
a channel region;
a source and a drain, located at two opposite ends of the channel region in a third direction;
the third direction being perpendicular to a surface of the base, and both the first direction and the second direction being perpendicular to the third direction; and
a gate, located on a side, in two opposite sides of the channel region in the first direction, away from another transistor; and
forming a plurality of connection structures between a channel region of the first transistor and a channel region of the second transistor, the channel region of the first transistor being connected to the channel region of the second transistor by the connection structure.

12. The method for manufacturing a semiconductor structure according to claim 11, wherein the forming, on the base, a plurality of transistor groups arranged in an array in a first direction and a second direction intersecting with each other comprises:
forming a plurality of first trenches and a plurality of second trenches arranged at intervals in the first direction on a first surface of the base, and forming a plurality of third trenches arranged in an array in the first direction and the second direction on a remaining part of the base; the first trench, the second trench, and the third trench dividing the base into a plurality of active pillar groups; and the second trench dividing the active pillar groups into a first active pillar and a second active pillar; and
separately performing doping processing on a first end and a second end, opposite to each other in a third direction, of each of the first active pillar and the second active pillar, and a middle part between the two ends, to form a source, a drain, and a channel region, wherein the doped first active pillar is configured to form the first transistor, and the doped second active pillar is configured to form the second transistor; the first end is an end close to a second surface of the base; and the first surface and the second surface are two surfaces of the base opposite to each other in the third direction.

13. The method for manufacturing a semiconductor structure according to claim 12, wherein a size of the first trench in the first direction is greater than a size of the second trench in the first direction.

14. The method for manufacturing a semiconductor structure according to claim 12, further comprising:
before the third trench is formed, forming a first insulating layer in the first trench, and forming a second insulating layer in the second trench; and
the forming a plurality of connection structures comprising:
removing a part of the second insulating layer, wherein a surface of a remaining part of the second insulating layer away from the second surface is higher than a surface of a first end of each of the first active pillar and the second active pillar away from the second surface;
filling with a connection structure material layer at a location at which the second insulating layer is removed; and
removing a part of the connection structure material layer, wherein a surface of a remaining part of the connection structure material layer away from the second surface is lower than a surface of a second end of each of the first transistor and the second transistor away from the first surface;
and the remaining part of the connection structure material layer is configured to form the connection structure.

15. The method for manufacturing a semiconductor structure according to claim 14, further comprising:
forming, by the remaining part of the connection structure material layer, the connection structure directly;
or
removing a part of the second insulating layer between the third insulating layers adjacent to each other in the first direction that is corresponding to the remaining part of the connection structure material layer, to form the connection structure.

16. The method for manufacturing a semiconductor structure according to claim 14, further comprising:
forming an isolation structure penetrating the first insulating layer; and
removing a part of the first insulating layer to form a word line material layer, wherein a surface of the word line material layer close to the first surface is lower than the first surface; and the isolation structure divides the word line material layer into two word lines.

17. The method for manufacturing a semiconductor structure according to claim 16, further comprising:
forming a plurality of bit lines on the plurality of first surfaces, wherein the plurality of bit lines are arranged in parallel in the second direction, and each of the bit lines is connected to a second end of each transistor in a row of transistor groups disposed in the first direction.

18. The method for manufacturing a semiconductor structure according to claim 17, further comprising:
providing a substrate, to form a peripheral circuit in the substrate;
bonding the base to the substrate, to form a bonding layer between the substrate and the bit line; and
performing thinning processing on the second surface of the base after the bonding operation is performed, to expose a first end of each transistor in the transistor group.

19. The method for manufacturing a semiconductor structure according to claim 18, wherein the bonding the base to the substrate comprises:
bonding the base to the substrate in a hybrid bonding manner.

20. The method for manufacturing a semiconductor structure according to claim 18, further comprising:
forming a plurality of storage structures on the exposed first end of each transistor in the transistor group, wherein each of the storage structures is connected to one of a source and a drain of a corresponding first transistor or one of a source and a drain of a corresponding second transistor.
